(19) United States
(12) Patent Application Publication
(10) Pub. No.: US 2024/0422970 A1
(43) Pub. Date: Dec. 19, 2024

(54) THREE-DIMENSIONAL (3D) VERTICAL MEMORY DEVICE AND METHOD OF MANUFACTURING SAME

(71) Applicant: SAMSUNG ELECTRONICS CO., LTD., SUWON-SI (KR)

(72) Inventor: Seulji SONG, Suwon-si (KR)

(21) Appl. No.: 18/529,007

(22) Filed: Dec. 5, 2023

(30) Foreign Application Priority Data
Jun. 15, 2023 (KR) 10-2023-0077011

(51) Int. Cl. H10B 43/20; H10B 41/10; H10B 41/20; H10B 43/10

(52) U.S. Cl. CPC H10B 43/20; H10B 41/10; H10B 41/20; H10B 43/10

(57) ABSTRACT

A 3D vertical memory device includes a substrate and an electrode structure extending in a vertical direction on the substrate. The electrode structure has a shape of a first cylinder and includes a first electrode and a switching material layer. A gate stack structure includes a gate electrode and an interlayer insulating layer alternately stacked on the substrate along a sidewall of the electrode structure. The gate electrode is electrically connected to the switching material layer. The electrode structure is arranged in a two-dimensional array structure on a plane perpendicular to the vertical direction, and constitutes a plurality of lines extending in a first direction. The electrode structures of two lines adjacent to each other in a second direction are arranged in a zigzag manner. A partition wall pillar having a shape of a second cylinder is arranged between the electrode structures adjacent to each other in the first direction.

### CROSS-REFERENCE TO RELATED APPLICATION

This application claims priority under 35 U.S.C. § 119 to Korean Patent Application No. 10-2023-0077011, filed on Jun. 15, 2023 in the Korean Intellectual Property Office, the disclosure of which is incorporated by reference in its entirety herein.

### 1. TECHNICAL FIELD

The present inventive concept relates to a semiconductor memory device, and more particularly, to a three-dimensional vertical memory device and a manufacturing method therefor.

### 2. DISCUSSION OF RELATED ART

The demand for high-capacity semiconductor memory devices has increased along with increased demands for the miniaturization, multifunctionality and high performance of electronic products. An increased degree of integration is necessary to provide high-capacity semiconductor memory devices. Since the degree of integration of two-dimensional (2D) semiconductor memory devices in the art is mainly determined by an area occupied by a unit memory cell, the degree of integration of 2D semiconductor devices has increased. However, the integration level is still limited. Accordingly, a three-dimensional (3D) semiconductor memory device in which memory capacity may be increased by stacking a plurality of memory cells in a vertical direction on a substrate is in development.

### SUMMARY

The technical idea of embodiments of the present disclosure provides a three-dimensional (3D) vertical memory device with increased operating speed and increased leaning margin while having a high aspect ratio, and a manufacturing method therefor.

The objectives of embodiments of the present disclosure are not limited to the objectives described above, and other objectives could be clearly understood by a person having ordinary skill in the art from the descriptions below.

According to an embodiment of the present disclosure, a three-dimensional (3D) vertical memory device includes a substrate. An electrode structure extends in a vertical direction on the substrate. The electrode structure has a shape of a first cylinder. The electrode structure comprises a first electrode and a switching material layer. A gate stack structure comprises a gate electrode and an interlayer insulating layer that are alternately stacked on the substrate along a sidewall of the electrode structure. The gate electrode is electrically connected to the switching material layer. The electrode structure is arranged in a two-dimensional array structure on a plane perpendicular to the vertical direction, and constitutes a plurality of lines extending in a first direction on the plane. On the plane, the electrode structures of two lines adjacent to each other in a second direction perpendicular to the first direction are arranged in a zigzag manner in the first direction with an offset of a ½ pitch in the first direction. A partition wall pillar having a shape of a second cylinder is arranged between the electrode structures adjacent to each other in the first direction.

According to an embodiment of the present disclosure, a three-dimensional (3D) vertical memory device includes a substrate. A first electrode is on the substrate. The first electrode extends in a vertical direction and has a shape of a first cylinder. A switching material layer has a circular pipe shape extending in the vertical direction and surrounds the first electrode A gate stack structure comprises a gate electrode and an interlayer insulating layer that are alternately stacked on the substrate along a sidewall of the switching material layer. The gate electrode is electrically connected to the switching material layer. The first electrode and the switching material layer together have a shape of a second cylinder. The second cylinder is arranged in a two-dimensional array structure on a plane perpendicular to the vertical direction, and constitutes a plurality of lines extending in a first direction on the plane. On the plane, the second cylinders of two lines adjacent to each other in a second direction perpendicular to the first direction are arranged in a zigzag manner in the first direction with an offset of a ½ pitch in the first direction. A partition wall pillar having a shape of a third cylinder is arranged between the second cylinders adjacent to each other in the first direction.

According to an embodiment of the present disclosure, a three-dimensional (3D) vertical memory device includes a substrate. A first electrode is on the substrate. The first electrode extends in a vertical direction and has a shape of a first cylinder. A switching material layer comprises a plurality of switching elements that are spaced apart from each other by layer in the vertical direction. The plurality of switching elements each have a shape of two arcs surrounding a portion of the first electrode and facing each other. A gate stack structure comprises a gate electrode and an interlayer insulating layer that are alternately stacked on the substrate along a side wall of the first electrode. The gate electrode is electrically connected to the switching material layer. The first cylinder is arranged in a two-dimensional array structure on a plane perpendicular to the vertical direction, and constitutes a plurality of lines extending in a first direction on the plane. On the plane, the first cylinders of two lines adjacent to each other in a second direction perpendicular to the first direction are arranged in a zigzag manner in the first direction with an offset of a ½ pitch in the first direction. A partition wall pillar having a shape of a second cylinder is arranged between the first cylinders adjacent to each other in the first direction.

### BRIEF DESCRIPTION OF THE DRAWINGS

Embodiments of the inventive concept will be more clearly understood from the following detailed description taken in conjunction with the accompanying drawings in which:

FIGS. 1A to 1C are respectively a plan view, a cross-sectional view, and a perspective view of a three-dimensional (3D) vertical memory device according to embodiments of the present disclosure;

FIGS. 2A to 2C are respectively a plan view, a cross-sectional view, and a perspective view of a 3D vertical memory device according to embodiments of the present disclosure;

FIGS. 3A to 3C are respectively a plan view, a cross-sectional view, and a perspective view of a 3D vertical memory element according to embodiments of the present disclosure;

FIGS. 4A to 4C are a conceptual diagram for describing an electrode structure arrangement rule, and plan views showing horizontal sizes of the 3D vertical memory devices of FIGS. 1A and 3A according to embodiments of the present disclosure;

FIGS. 5A to 5D are perspective views, a circuit structure, and a graph of operating characteristics, of a Comparative Example and an embodiment of FIG. 1;

FIGS. 6 to 12B are plan views and cross-sectional views that show a process of manufacturing the 3D vertical memory devices of FIGS. 1A and 1B according to embodiments of the present disclosure; and

FIGS. 13A to 13E are cross-sectional views showing a process of manufacturing the 3D vertical memory device of FIG. 2B according to embodiments of the present disclosure.

### DETAILED DESCRIPTION OF EMBODIMENTS

Hereinafter, embodiments are described in detail with reference to the accompanying drawings. In the drawings, the same reference characters are used for the same element, and redundant descriptions thereof may be omitted for economy of description

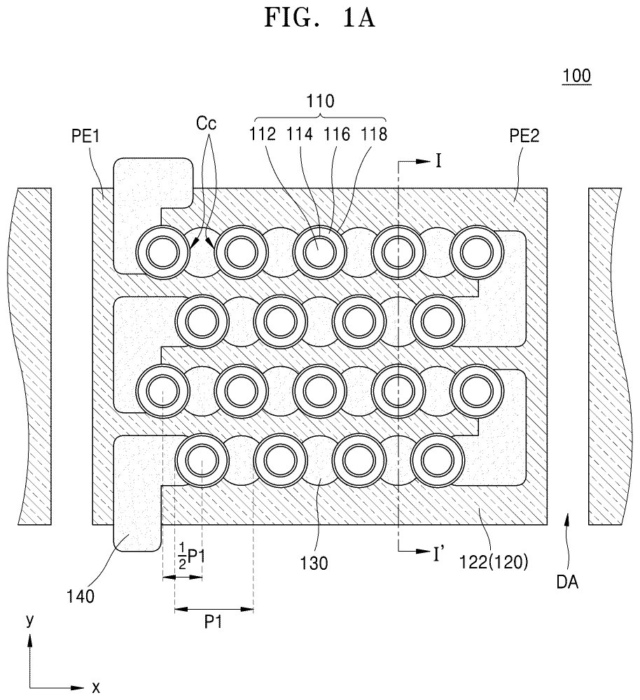

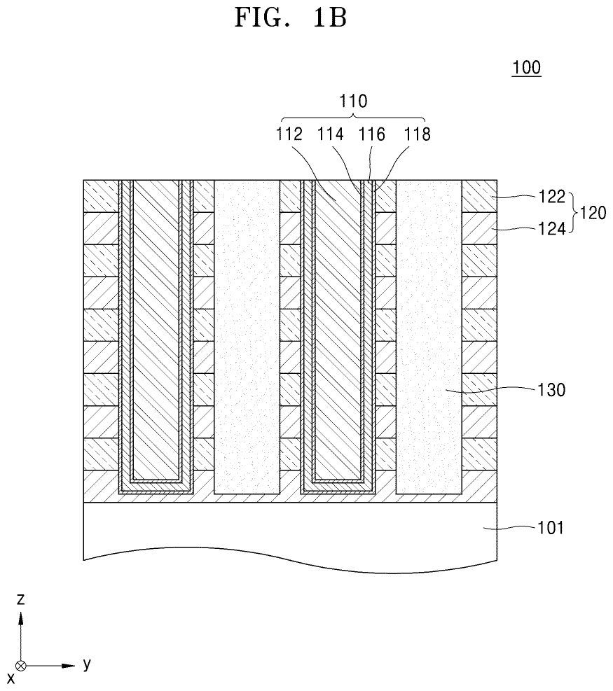

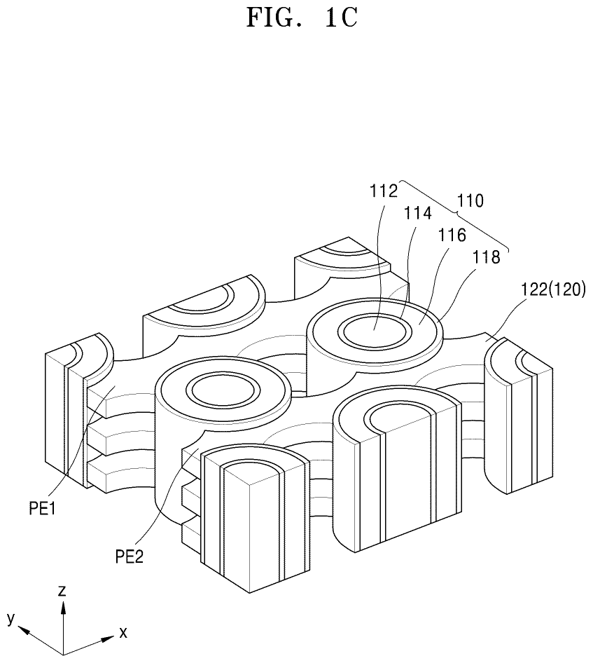

FIGS. 1A to 1C are respectively a plan view, a cross-sectional view, and a perspective view, of a three-dimensional (3D) vertical memory device 100, according to embodiments of the present disclosure.

Referring to FIGS. 1A to IC, the 3D vertical memory device 100 of an embodiment may include a substrate 101, an electrode structure 110, a gate stack structure 120, a partition wall pillar 130, and a trim pattern 140.

In an embodiment, the substrate 101 may include silicon (Si), for example, single crystal Si, polycrystalline Si (poly Si), or amorphous Si. However, a material of the substrate 101 is not necessarily limited to Si. For example, in some embodiments, the substrate 101 may include a Group IV semiconductor such as germanium (Ge), Group IV-IV compound semiconductor such as silicon germanium (SiGe) or silicon carbide (SiC), or a Group III-V compound semiconductor such as gallium arsenide (GaAs), indium arsenide (InAs), and indium phosphide (InP).

In an embodiment, the substrate 101 may be based on a Si bulk substrate. In addition, the substrate 101 may be based on a silicon on insulator (SOI) substrate or a germanium-on-insulator (GeOI) substrate. However, the substrate 101 is not necessarily limited to bulk, SOI, or GeOI substrates, and may be a substrate based on an epitaxial wafer, a polished wafer, or an annealed wafer in some embodiments. The substrate 101 may include a conductive area, for example, a well doped with impurities, or various structures doped with impurities. In addition, the substrate 101 may constitute a p-type substrate or an n-type substrate, depending on a type of impurity ions to be doped. In an embodiment, a peripheral circuit and a wiring layer connected to the peripheral circuit may be disposed on a partial area of the substrate 101.

In an embodiment, the electrode structure 110 may be arranged in a two-dimensional array on an x-y plane, as shown in FIG. 1A. For example, the electrode structures 110 may be arranged to be spaced apart from each other in each of an x direction and a y direction. The electrode structures 110 may constitute a line in the x direction, and the electrode structures 110 adjacent to each other in the x direction may be separated from each other by the partition wall pillar 130. In addition, the electrode structures 110 on two lines adjacent to each other in the y direction may be connected to a gate electrode 122 of the gate stack structure 120.

In an embodiment, the electrode structures 110 constituting a line in the x direction may be arranged in a zigzag manner in the x direction, on the two lines adjacent to each other in the y direction. For example, the electrode structures 110 may be arranged with a first pitch P1 in the x direction, and the electrode structures 110 may be arranged with an offset of ½ of the first pitch P1 in the x direction between the two lines adjacent to each other in the y direction.

In an embodiment, the electrode structure 110 may have a cylindrical shape (e.g., a first cylinder shape) extending in a direction perpendicular to the upper surface of the substrate 101, such as in a z direction. For example, in an embodiment, in a horizontal cross section, the cylinder shape of the electrode structure 110 may be circular. However, a shape of the electrode structure 110 is not necessarily limited to the cylindrical shape. For example, in some embodiments, the electrode structure 110 may have a shape of an elliptical pillar or a polygonal pillar.

In an embodiment, the electrode structure 110 may include a first electrode 112, a first carbon layer 114, a switching material layer 116, and a second carbon layer 118 from a center. However, embodiments of the present disclosure are not necessarily limited thereto. For example, in some embodiments, at least one of the first carbon layer 114 and the second carbon layer 118 may be omitted. In the 3D vertical memory device 100 of an embodiment, the first electrode 112 may constitute a vertical bit line.

The first electrode 112 may have a cylindrical shape extending in the z direction, on the upper surface of the substrate 101. However, a shape of the first electrode 112 is not necessarily limited to the cylindrical shape. For example, in some embodiments the first electrode 112 may have a shape of an elliptical pillar or a polygonal pillar. In an embodiment as shown in FIG. 1A, the first electrode 112 may be arranged in a central portion of the electrode structure 110 and a diameter of the first electrode 112 may be less than a diameter of the electrode structure 110. The first electrode 112 may include a conductive material. For example, in an embodiment the first electrode 112 may include a doped semiconductor material, a metal, a conductive metal oxide, and a conductive metal nitride. In an embodiment, a conductive contact may be disposed under or over the electrode structure 110, and the conductive contact may be connected to the first electrode 112.

In an embodiment, the first carbon layer 114 may cover a bottom surface and lateral side surfaces of the first electrode 112. Accordingly, the first carbon layer 114 may have a circular pipe shape with one side closed. However, embodiments of the present disclosure are not necessarily limited thereto. For example, in some embodiments the first carbon layer 114 may have an opened circular pipe shape.

In an embodiment, the switching material layer 116 may cover a bottom surface and lateral side surfaces of the first carbon layer 114. Accordingly, the switching material layer 166 may have a circular pipe shape with one side closed. However, in some embodiments, the switching material layer 116 may have an opened circular pipe shape. In an embodiment, the switching material layer 116 may be connected (e.g., electrically connected) to the gate electrode 122 of the gate stack structure 120.

The switching material layer 116 may serve as a self-selecting storage device. In the present specification, the self-selecting storage device may refer to a device that may act as both a selecting device and a storage device. According to these characteristics of the switching material layer 116, the 3D vertical memory device 100 of an embodiment may be described as a selector only memory (SOM) device.

In an embodiment, the switching material layer 116 may include a chalcogenide material such as glass and/or a chalcogenide alloy that serves as a self-selecting storage device. The switching material layer 116 may respond to an applied voltage such as a program pulse. For example, with respect to an applied voltage less than a threshold voltage, the switching material layer 116 may maintain an electrically non-conductive state, such as an off state. In addition, in response to an applied voltage greater than the threshold voltage, the switching material layer 116 may be changed to an electrically conductive state, such as an on state. In an embodiment, a threshold voltage of the switching material layer 116 may vary depending on a polarity of an applied voltage. For example, the threshold voltage of the switching material layer 116 may vary depending on whether a polarity of a program pulse is positive or negative. Accordingly, in the 3D vertical memory device 100 of an embodiment, a bipolar voltage may be required for driving of the memory device.

The switching material layer 116 may include a chalcogenide material of which the phase does not change during operation. In an embodiment the switching material layer 116 may include, for example, indium (In)-antimony (Sb)-tellurium (Te) (IST), germanium (Ge)—Sb—Te (GST), Te, arsenic (As)—Ge (OTS), GeAsSe, GeSe, GeAsSeS, Ge, Sb, Te, Si, nickel (Ni), gallium (Ga), As, silver (Ag), tin (Sn), gold (Au), mercury (Pb), bismuth (Bi), In, selenium (Se), oxygen (O), sulfur(S), nitrogen (N), carbon (C), ytterbium (Yb), scandium (Sc), and a combination thereof. Here, IST may include, for example, In₂Sb₂Te₅, InSb₂Te₄, InSb₄Te₇, etc. GST may include, for example, Ge₈Sb₅Te₈, Ge₂Sb₂Te₅, GeSb₂Te₄, GeSb₄Te₇, Ge₄Sb₄Te₇, etc. In some embodiments, a chalcogenide material may be glass or amorphous chalcogenide.

In an embodiment, the second carbon layer 118 may cover a bottom surface and lateral side surfaces of the switching material layer 116. Accordingly, the second carbon layer 118 may have a circular pipe shape with one side closed. However, embodiments of the present disclosure are not necessarily limited thereto. For example, in some embodiments the second carbon layer 118 may have an opened circular pipe shape.

For reference, in an embodiment in which a conductive contact is disposed under the electrode structure 110, and the first carbon layer 114, the switching material layer 116, and the second carbon layer 118 have a circular pipe structure with a closed bottom surface, the conductive contact may be connected to the first electrode 112 through the first carbon layer 114, the switching material layer 116, and the second carbon layer 118. Unlike this, in an embodiment in which the first carbon layer 114, the switching material layer 116, and the second carbon layer 118 have an opened circular pipe structure that does not have a bottom surface, the conductive contact may be directly connected to the first electrode 112.

The gate stack structure 120 may include a gate electrode 122 and an interlayer insulating layer 124. As shown in FIG. 1B, the gate electrode 122 and the interlayer insulating layer 124 may be alternately stacked on the substrate 101 along a side surface of the electrode structure 110. In the 3D vertical memory device 100 of an embodiment, the gate electrode 122 may constitute a word line.

In an embodiment, the gate electrode 122 may have a plate shape. For example, the gate electrode 122 may have a structure to be integrally connected in a plate shape in each layer. Accordingly, the gate electrode 122 may be described as a plate electrode. In addition, in some embodiments, the gate electrode 122 may be described as a word line plate.

In the 3D vertical memory device 100 of an embodiment, the gate electrode 122 may have a split plate electrode shape. For example, in each layer, the gate electrode 122 may include, in an x direction, a first plate electrode PE1 on the left side, and a second plate PE1 on the right side. In addition, the first plate electrode PE1 and the second plate electrode PE2 may have a comb shape crossed with each other. For example, with respect to a line on which the electrode structure 110 is arranged in the x direction, the first plate electrode PE1 and the second plate electrode PE2 may be arranged at opposite sides in a y direction. In the 3D vertical memory device 100 of an embodiment in which the gate electrode 122 may have a split plate electrode shape, parasitic caps on a word line may be reduced and operating speed may be increased. In addition, in an embodiment in which the gate electrode 122 may have a split plate electrode shape, an area in contact with a cell may be reduced, and cell leakage may be reduced, and thus, programming current may be increased.

In an embodiment, the gate electrode 122 may include a conductive material, for example, a doped semiconductor material, a metal, a conductive metal nitride, and a conductive metal oxide. The interlayer insulating layer 124 may include an insulating material, for example, silicon oxide, silicon nitride, or silicon oxynitride. In the 3D vertical memory device 100 of an embodiment, the interlayer insulating layer 124 may include silicon oxide. However, a material of the interlayer insulating layer 124 is not necessarily limited to silicon oxide.

The partition wall pillar 130 may be arranged between the electrode structures 110 arranged in the x direction. In an embodiment, the partition wall pillar 130 may have an approximately circular pillar shape (e.g., a second cylinder shape), but an outer portion thereof may be partially invaded by the electrode structures 110 arranged at opposite sides in the x direction Accordingly, in a horizontal cross section the partition wall pillar 130 may include a concave portion Cc at opposite sides thereof, in the x direction. In an embodiment, the partition wall pillar 130 may include an insulating material, for example, silicon oxide, silicon nitride, or silicon oxynitride. In the 3D vertical memory device 100 of an embodiment, the partition wall pillar 130 may include silicon oxide. However, a material of the partition wall pillar 130 is not necessarily limited to silicon oxide. For reference, in FIG. 1C, the interlayer insulating layer 124 and the partition wall pillar 130 are omitted An empty space in the x direction between the electrode structures 110 may correspond to the partition wall pillar 130, and an empty space in the z direction between the gate electrodes 122 may correspond to the interlayer insulating layer 124.

The trim pattern 140 may be arranged at opposite edges of a cell block in the x direction. In an embodiment, the cell block may be defined through a separation area DA arranged in the x direction. For example, the separation area DA may extend in the y direction and may separate cell blocks adjacent to each other in the x direction. For reference, the cell block may extend in the y direction, a pad having a staircase shape may be arranged at an edge portion of the cell block, and a vertical contact may be connected to the pad. Through the vertical contact and the pad, a word line voltage may be applied to the gate electrode 122 of each layer.

In an embodiment, the trim pattern 140 may have an inverted “L” shape or an “L” shape in a plan view. In addition, the trim pattern 140 may have a width covering (e.g., overlapping) two partition wall pillars 130 in the y direction. For example, two lines adjacent to each other in the y direction from among lines on which the electrode structures 110 are arranged in the x direction may be in contact with each other through the electrode structure 110 with the trim pattern 140 arranged on the left or right side in the x direction. In an embodiment, the trim patterns 140 on the left side in the x direction and the trim patterns 140 on the right side in the x direction may be arranged at staggered positions in the y direction with one trim pattern 140 having an “L” shape and the other trim pattern 140 having an inverted “L” shape. In addition, two trim patterns 140 facing each other in the x direction and adjacent to each other in the y direction may together cover (e.g., overlap) one line on which the electrode structures 110 are arranged in the x direction, and may be arranged in a point-symmetrical structure with respect to any one portion of the line, for example, the electrode structure 110 of a central portion of the line.

In an embodiment, the trim pattern 140 may include an insulating material, for example, silicon oxide, silicon nitride, or silicon oxynitride. In the 3D vertical memory device 100 of an embodiment, the trim pattern 140 may be formed together with the partition wall pillar 130. Accordingly, the trim pattern 140 may include silicon oxide. However, a material of the trim pattern 140 is not necessarily limited to silicon oxide.

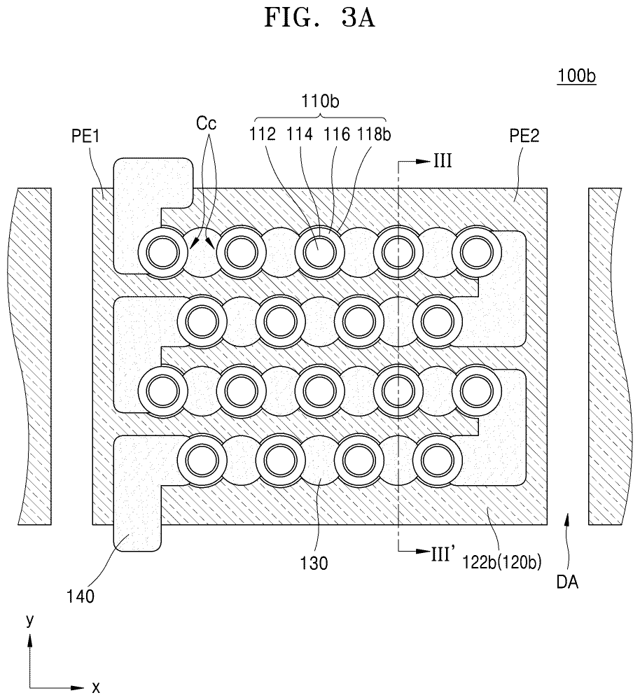

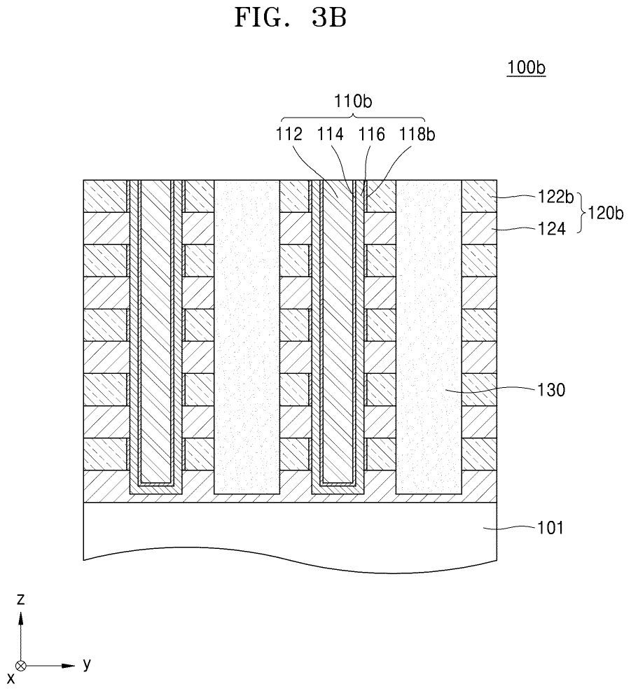

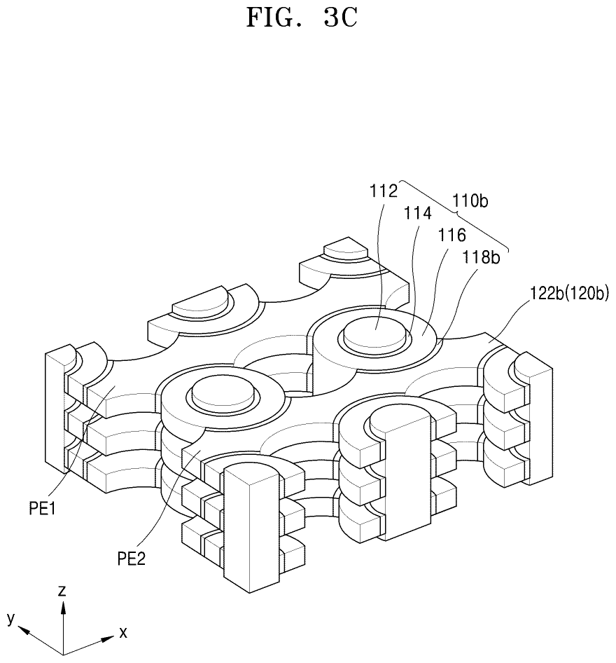

In the 3D vertical memory device 100 of an embodiment, the electrode structure 110 having the first electrode 112 and the switching material layer 116 may extend in a vertical direction and may have a vertical structure in which the gate electrodes 122 are stacked along a sidewall of the electrode structure 110. Accordingly, in the 3D vertical memory device 100 of an embodiment, a large-capacity memory device with significantly increased integration may be implemented. In addition, in the 3D vertical memory device 100 of an embodiment, the gate electrode 122 may have a split plate electrode shape. Accordingly, in the 3D vertical memory device 100 of an embodiment, parasitic caps may be reduced to increase an operating speed, and an area in contact with a cell may be reduced to reduce cell leakage and increase programming current. Further, in the 3D vertical memory device 100 of an embodiment, the electrode structures 110 may be arranged in a line shape in the x direction, and may be separated from each other by the partition wall pillar 130 having a cylindrical shape. As described above, the partition wall pillar 130 having the cylindrical shape has a structure arranged between the electrode structures 110, so as to effectively prevent a leaning defect that may occur while forming a high aspect ratio line pattern on the gate stack structure 120 of several tens to hundreds of layers. The leaning defect is described in greater detail with reference to FIGS. 3A to 3C.

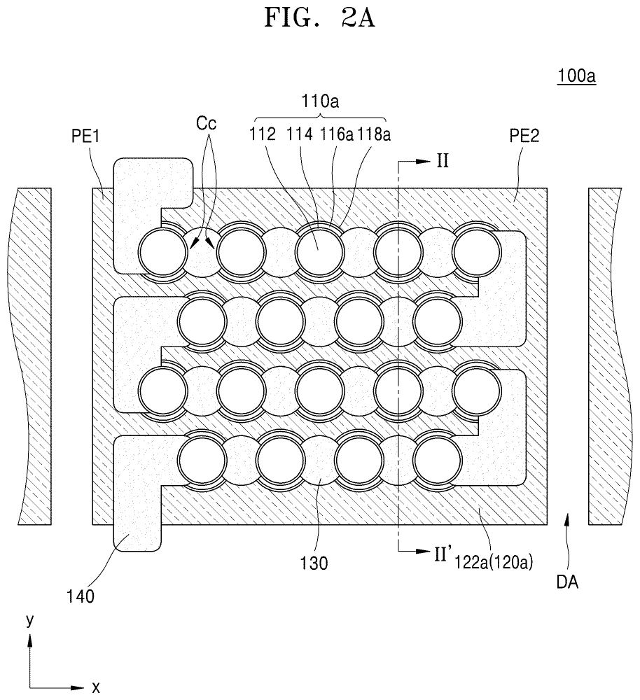

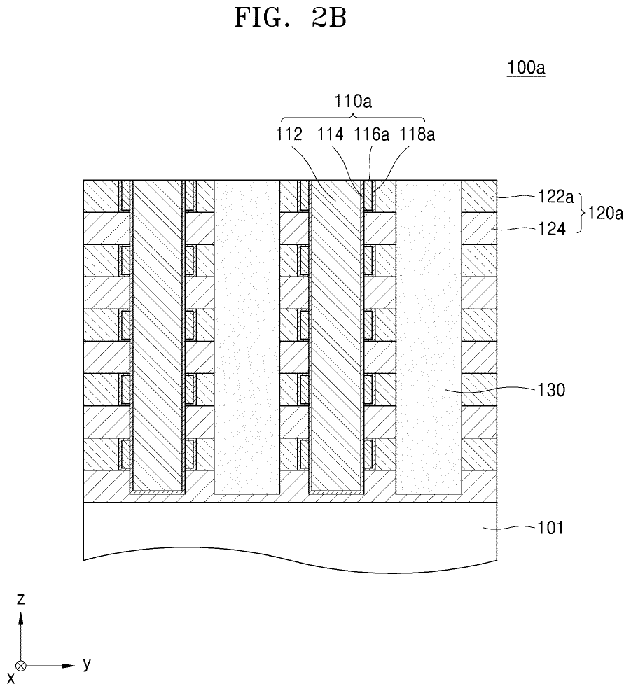

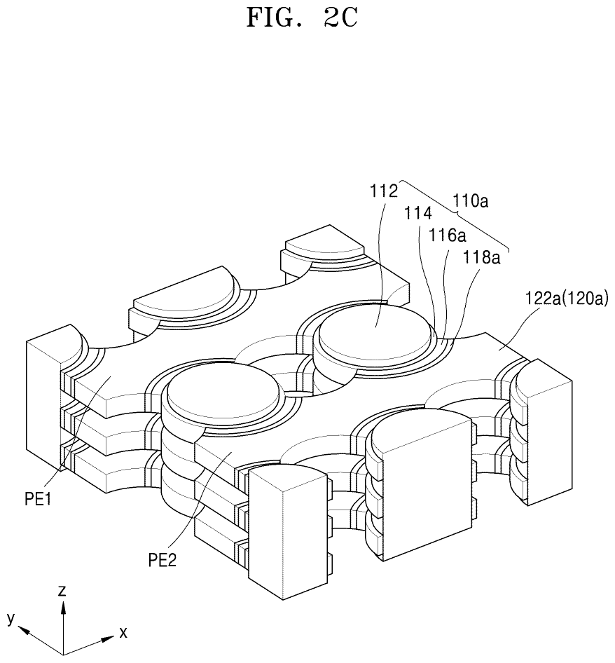

FIGS. 2A to 2C are a plan view, a cross-sectional view, and a perspective view of a 3D vertical memory device according to embodiments of the present disclosure. Details described with reference to FIGS. 1A to 1C may be briefly described or omitted for economy of description.

Referring to FIGS. 2A to 2C, a 3D vertical memory device 100a of an embodiment may differ from the 3D vertical memory device 100 of embodiments shown in FIGS. 1A-1C with respect to the structure of an electrode structure 110a. For example, the 3D vertical memory device 100a of an embodiment may include a substrate 101, the electrode structure 110a, a gate stack structure 120a, a partition wall pillar 130, and a trim pattern 140. The substrate 101, the gate stack structure 120a, the partition wall pillar 130, and the trim pattern 140 are as described with reference to the substrate 101, the gate stack structure 120, the partition wall pillar 130, and the trim pattern 140 of the 3D vertical memory device of an embodiment shown in FIG. 1A. However, in the gate stack structure 120a shown in FIGS. 2A-2C, a gate electrode 122a may have a width that decreases in a y direction at a portion in direct contact with the electrode structure 110a. A width of the gate electrode 122a is described in greater detail in the description of the electrode structure 110a below

In an embodiment, the electrode structure 110a may be arranged in a two-dimensional array structure on an x-y plane. For example, the electrode structures 110a may constitute a line in the x direction and adjacent first electrodes 112 may be separated from each other by the partition wall pillar 130 in the x direction. In addition, the electrode structures 110a on two lines adjacent to each other in the y direction may be connected to the gate electrode 122a of the gate stack structure 120a. In addition, in an embodiment the electrode structures 110a constituting the line in the x direction may be arranged in a zigzag manner in the x direction on the two adjacent lines, and may have an offset of a ½ pitch in the x direction.

The electrode structure 110a may include a first electrode 112, a first carbon layer 114, a switching material layer 116a, and a second carbon layer 118a. However, embodiments of the present disclosure are not necessarily limited thereto. For example, in some embodiments, at least one of the first carbon layer 114 and the second carbon layer 118a may be omitted. In the 3D vertical memory device 100a of an embodiment, the first electrode 112 may constitute a vertical bit line.

The first electrode 112 may have a cylindrical shape extending in a z direction on an upper surface of the substrate 101. However, a shape of the first electrode 112 is not necessarily limited to the cylindrical shape. For example, the first electrode 112 may have a shape of an elliptical pillar or a polygonal pillar in some embodiments. In an embodiment, a conductive contact may be disposed under or over the electrode structure 110a, and the conductive contact may be connected to the first electrode 112.

In an embodiment, the first carbon layer 114 may cover a bottom surface and lateral side surfaces of the first electrode 112. Accordingly, the first carbon layer 114 may have a circular pipe shape with one side closed. However, in some embodiments, the first carbon layer 114 may have an opened circular pipe shape.

The switching material layer 116a may include a plurality of switching elements spaced apart from each other for each layer by the interlayer insulating layer 124, in a vertical direction on the substrate 101, such as the z direction. In an embodiment, each of the switching elements may have a shape of two arcs facing each other and surrounding a portion of the first carbon layer 114. For example, the switching elements of the switching material layer 116a may be arranged in an arc shape only on layers on which the gate electrode 122a of the gate stack structure 120a is disposed. For example, as can be understood from FIGS. 2A and 2C, each of the switching elements of the switching material layer 116a may have a shape in which a portion in direct contact with the partition wall pillar 130 at opposite sides thereof in the x direction is removed from a circular ring shape surrounding the first carbon layer 114. Accordingly, the first carbon layer 114 may be in direct contact with the partition wall pillar 130 in the x direction. In an embodiment, the switching elements of the switching material layer 116a may be spaced apart and separated from the switching elements of another layer in the z direction.

As described above, since the switching material layer 116a has the switching elements and has a structure in which the switching elements are separated from each other in the z direction, diffusion between cells in the z direction may be blocked, and the reliability of the memory device may be increased. Other operating characteristics and specific materials of the switching material layer 116a are as described with reference to the switching material layer 116 of the 3D vertical memory device 100 of an embodiment shown in FIG. 1A.

The second carbon layer 118a may include a plurality of second carbon elements spaced apart from each other for each layer in the z direction to correspond to the switching elements of the switching material layer 116a. Each of the second carbon elements may have a shape of two arcs surrounding a switching element of a corresponding switching material layer 116a. For example, as can be understood from FIGS. 2A and 2C, the second carbon elements of the second carbon layer 118a and the switching elements of the switching material layer 116a have a shape of two arcs, so that the first carbon layer 114 may be in direct contact with the partition wall pillars 130 at opposite sides in the x direction. In an embodiment, similar to the switching material layer 116a, in the second carbon layer 118a, the second carbon elements may be spaced apart and separated from the second carbon elements in other layers in the z direction.

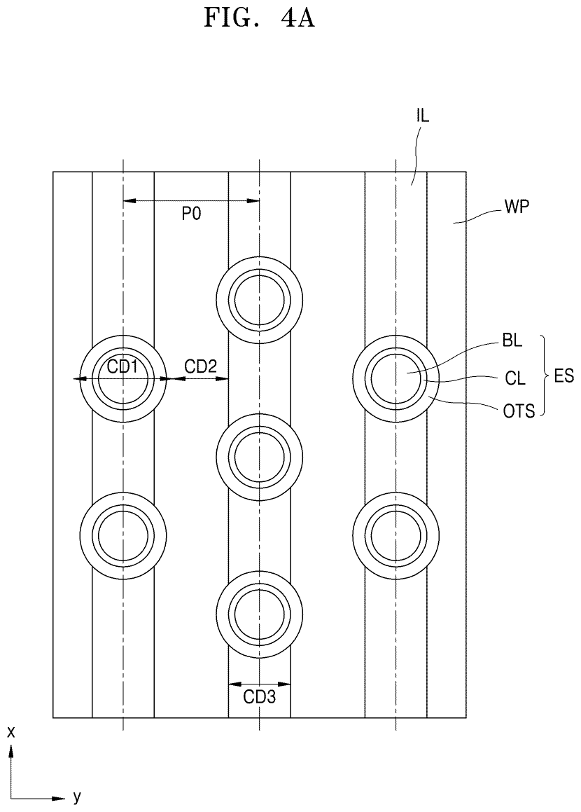

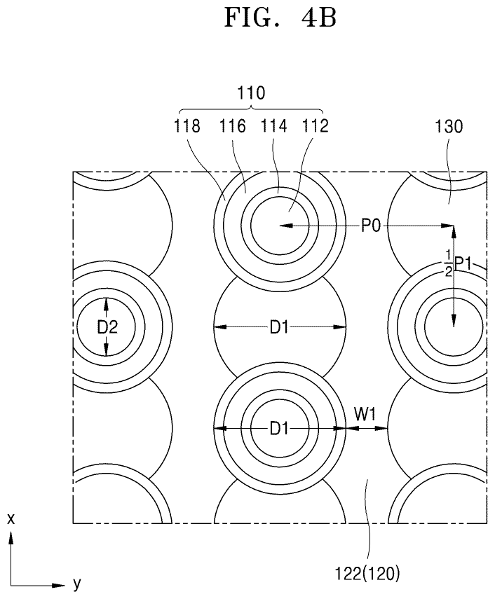

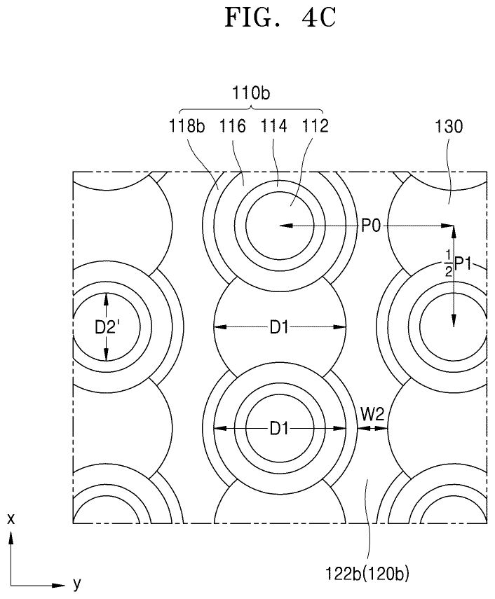

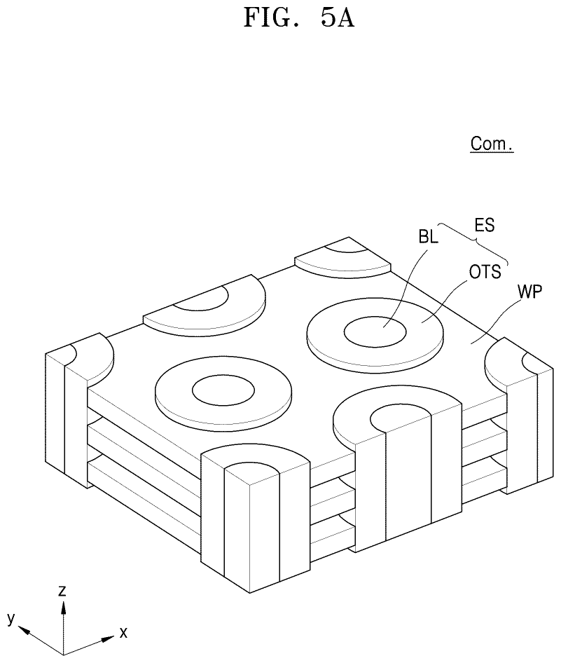

In an embodiment in which an open hole for forming the electrode structure 110a has a same size as an open hole for forming the electrode structure 110 in the 3D vertical memory device 100 in FIG. 1A, when thicknesses of the first carbon layer 114, the switching material layer 116, and the second carbon layer 118 of the electrode structure 110 are same as thicknesses of the first carbon layer 114, the switching material layer 116a, and the second carbon layer 118a of the electrode structure 110a, due to the nature of the process, a size, for example, the horizontal radius, of the first electrode 112 of the electrode structure 110a may be greater than the horizontal radius of the first electrode 112 of the electrode structure 110 of an embodiment shown in FIG. 1A. For example, in an embodiment in which the second carbon layers 118 and 118a are very thin, the horizontal radius of the first electrode 112 of the electrode structure 110a may be almost similar to the horizontal radius of the entire electrode structure 110. In addition, in the electrode structure 110a, when the switching material layer 116a and the second carbon layer 118a are arranged in a shape of two arcs at opposite sides in the y direction, the gate electrode 122a of the gate stack structure 120a may have a width in the y direction that decreases in a portion, e.g., the second carbon layer 118a, in direct contact with the electrode structure 110a. A size of the electrode structure 110a and a width of the gate electrode 122a are described in greater detail with reference to FIGS. 4A to 4C.

Depending on an embodiment, the 3D vertical memory device 100 may be formed such that the first electrode 112 of the electrode structure 110 of the 3D vertical memory device 100 of an embodiment shown in FIG. 1A and the first electrode 112 of the electrode structure 110a of the 3D vertical memory device 100 of an embodiment shown in FIG. 2A have substantially a same size. In this case, the open hole for forming the electrode structure 110a may have a size of the first electrode 112 of the electrode structure 110 or a size including the first carbon layer 114. Thereafter, through an extension process, the switching material layer 116a may be formed in a same thickness in which the switching material layer 116 is formed, and the second carbon layer 118a may be formed in a same thickness in which the second carbon layer 118 is formed. As a result, in terms of diameter in the y direction, the electrode structure 110 and the electrode structure 110 may have substantially the same size.

Similar to the 3D vertical memory device 100 of an embodiment shown in FIG. 1A, the 3D vertical memory device 100a of an embodiment shown in FIG. 2A may have effects of increasing integration, increasing operating speed, increasing programming current, and preventing leaning defects Furthermore, in the 3D vertical memory device 100a of an embodiment shown in FIG. 2A, the switching elements of the switching material layer 116a may have a structure of being separated in the z direction, thus blocking diffusion between cells and increasing the reliability of the memory device.

FIGS. 3A to 3C are respectively a plan view, a cross-sectional view, and a perspective view of a 3D vertical memory device 100b according to embodiments of the present disclosure. Details overlapping those of FIGS. 1A to 2C may be briefly described or omitted for economy of description.

Referring to FIGS. 3A to 3C, the 3D vertical memory device 100b of an embodiment may differ from the 3D vertical memory device 100 of FIG. 1A with respect to a structure of the electrode structure 110b. For example, the 3D vertical memory device 100b of an embodiment may include a substrate 101, an electrode structure 110b, a gate stack structure 120b, a partition wall pillar 130, and a trim pattern 140. The substrate 101, the gate stack structure 120b, the partition wall pillar 130, and the trim pattern 140 as shown in embodiments of FIGS. 3A-3C are as described with reference to the substrate 101, the gate stack structure 120, the partition wall pillar 130, and the trim pattern 140 of the 3D vertical memory device 100 of an embodiment of FIG. 1A.

In an embodiment, the electrode structure 110b may be arranged in a two-dimensional array structure on an x-y plane. For example, the electrode structures 110b may constitute a line in the x direction and adjacent first electrodes 112 may be separated from each other by the partition wall pillar 130 in the x direction. In addition, the electrode structures 110b on two lines adjacent to each other in the y direction may be connected to the gate electrode 122b of the gate stack structure 120b. In addition, in an embodiment the electrode structures 110b constituting the line in the x direction may be arranged in a zigzag manner in the x direction, on the two lines adjacent to each other in the y direction, and may have an offset of a ½ pitch in the x direction.

In an embodiment, the electrode structure 110b may include a first electrode 112, a first carbon layer 114, a switching material layer 116, and a second carbon layer 118b. In some embodiments, at least one of the first carbon layer 114 and the second carbon layer 118b may be omitted. In the 3D vertical memory device 100b of an embodiment shown in FIG. 3B, the first electrode 112 may constitute a vertical bit line. In an embodiment, the first electrode 112, the first carbon layer 114, and the switching material layer 116 in embodiments of FIGS. 3A-3C are as described with reference to the first electrode 112, the first carbon layer 114, and the switching material layer 116 of the electrode structure 110 of the 3D vertical memory device 100 of an embodiment of FIG. 1A.

The second carbon layer 118b may include a plurality of second carbon elements spaced apart from each other for each layer, in the z direction. In an embodiment, each of the second carbon elements may have a shape of two arcs facing each other and surrounding a portion of the switching material layer 116. For example, the second carbon elements of the second carbon layer 118b may be arranged to have an arc shape only on layers on which the gate electrode 122b of the gate stack structure 120b is disposed. For example, as can be understood from FIGS. 3A and 3C, each of the second carbon elements of the second carbon layer 118b may have a shape in which a portion in direct contact with the partition wall pillar 130 at opposite sides in the x direction is removed from a circular ring shape surrounding the switching material layer 116. Accordingly, the switching material layer 116 may be in direct contact with the partition wall pillar 130 in the x direction. In an embodiment, the second carbon elements of the second carbon layer 118b may be spaced apart and separated from the second carbon elements on other layers in the z direction.

FIGS. 4A to 4C are a conceptual diagram for describing an arrangement rule of an electrode structure, and plan views showing horizontal sizes of the 3D vertical memory devices of embodiments shown in FIGS. 1A and 3A.

Referring to FIG. 4A, in general, to ensure operating characteristics in a 3D vertical memory device, in terms of size in a plan view, considering a thickness of 20 nm of a switching material layer OTS, a thickness of 10 nm of an inner carbon layer CE, a CD variation of 10 nm of a high aspect ratio contact (HARC), and a ratio of 1.5 between a top surface and a bottom surface of the HARC, a diameter of a first CD CD1 of about 120 nm ((20+10+10)*1.5*2) needs to be ensured in an electrode structure ES. In addition, a pitch P0 needs to be maintained in an amount of at least 160 nm in the y direction, and considering a minimum margin of 30 nm for a replacement process of a gate electrode WP, a CD variation of 20 nm, and a photo process margin of 10 nm, a second CD CD2 needs to ensure about 60 nm between the electrode structure ES and an insulating layer IL having a line shape. A third CD CD3 of the insulating layer IL needs to ensure about 80 nm at most.

As the number of layers of a gate stack structure has recently increased, a line-shaped trench for forming the insulating layer IL having a line shape has become vulnerable to leaning defects due to a high aspect ratio, despite a width of 80 nm thereof. In addition, the trench has become longer than the width thereof in the x direction between separation areas, line width roughness (LWR) has also become weaker. In the present specification, the LWR may indicate a degree of uniformity and straightness of a width of a line pattern.

Referring to FIG. 4B, in an embodiment of the 3D vertical memory device 100 shown in FIG. 1A, the electrode structure 110 may include the second carbon layer 118 and may have a first diameter D1. In an embodiment, the first diameter D1 may be about 120 nm based on the minimum first CD CD1 described above. In this embodiment, a second diameter D2 of the first electrode 112 may be about 60 nm. In addition, the partition wall pillar 130 may have the first diameter D1, e.g., about 120 nm, which is equal to the diameter of the electrode structure 110. However, depending on the embodiment, the diameter of the partition wall pillar 130 may be greater or less than 20 nm.

A pitch P0 may still be maintained 160 nm in the y direction. Accordingly, a first width W1 in the y direction of the gate electrode 122 between the electrode structure 110 and the partition wall pillar 130 may be about 40 nm. In addition, ½ of the first pitch P1 in the x direction may be about 90 nm. However, the first pitch P1 in the x direction may be flexible to some extent, depending on the diameter of the partition wall pillar 130 and a distance between the electrode structures 110.

Referring to FIG. 4C, in an embodiment in which the 3D vertical memory device 100b is an embodiment shown in FIG. 3A, the electrode structure 110b may have the first diameter D1 excluding the second carbon layer 118b. In an embodiment, the first diameter D1 may be about 120 nm based on the minimum first CD CD1 described above In addition, the second diameter D2′ of the first electrode 112 may be about 60 nm. However, in some embodiments, the diameter of the electrode structure 110b excluding the second carbon layer 118b may be greater than about 120 nm, and the diameter of the first electrode 112 may be greater than about 60 nm.

Comparing the electrode structures 110 and 110b of the 3D vertical memory devices 100 and 100b of embodiments of FIGS. 1A and 3A, the first electrodes 112 may both be about 60 nm, and when the first carbon layers 114 have the same thickness, the switching material layer 116 of the electrode structure 110b may be greater than the switching material layer 116 of the electrode structure 110. Unlike the above, when the first carbon layers 114 have the same thickness and the switching material layers 116 have the same thickness, the diameter of the first electrode 112 of the electrode structure 110b may be greater than the diameter of the first electrode 112 of the electrode structure 110.

The partition wall pillar 130 may have the first diameter D1, such as about 120 nm. However, depending on an embodiment, the diameter of the partition wall pillar 130 may be greater or less than 120 nm. The pitch P0 in the y direction may still be maintained at about 160 nm. Accordingly, a second width W2 in the y direction of the gate electrode 122b between the electrode structure 110b and the partition wall pillar 130 may be less than about 40 nm. For example, in an embodiment the second width W2 in the y direction of the gate electrode 122b between the electrode structure 110b and the partition wall pillar 130 may be less than the first width W1 by a thickness of the second carbon layer 118b. In addition, ½ of the first pitch P1 in the x direction may be about 90 nm. However, the first pitch P1 may be flexible to some extent, depending on the diameter of the partition wall pillar 130 and an interval of the electrode structures 110b.

The 3D vertical memory device 100a of an embodiment shown in FIG. 2A may be similar to the 3D vertical memory device 100b of an embodiment shown in FIG. 3A, except that, in the 3D vertical memory device 100a of FIG. 2A, the diameter up to the first carbon layer 114 is the first diameter D1, and the switching material layer 116a and the second carbon layer 118a each have a shape of two arcs and are arranged outside the first carbon layer 114. Further, a width in the y direction of the gate electrode 122a between the electrode structure 110a and the partition wall pillar 130 may be less than the first width W1 by a thickness of the sum of the switching material layer 116a and the second carbon layer 118a.

In a case of the 3D vertical memory devices 100, 100a, and 100b, instead of the insulating layer IL having a line shape, the partition wall pillar 130 having a cylindrical shape may be arranged between the electrode structures 110, 110a, and 100b. Accordingly, despite the increase in the number of layers of the gate stack structures 120, 120a, and 120b, a leaning defect may be effectively prevented. In addition, since the partition wall pillar 130 has a cylindrical shape, a problem of an LWR defect may also not occur.

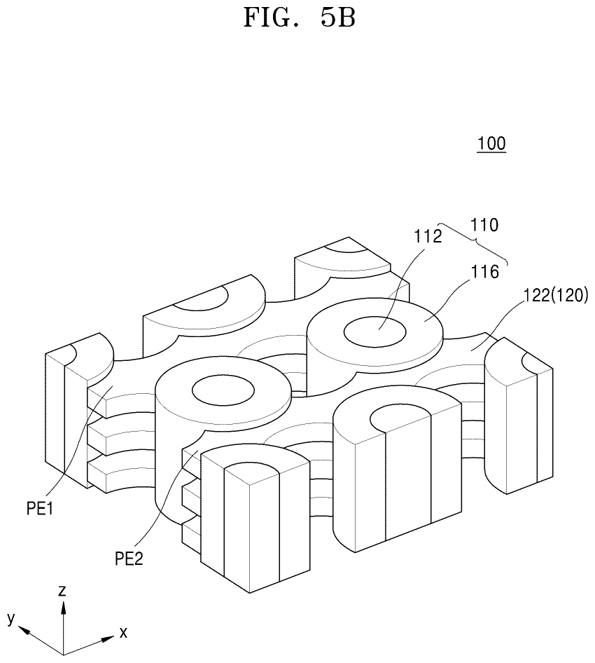

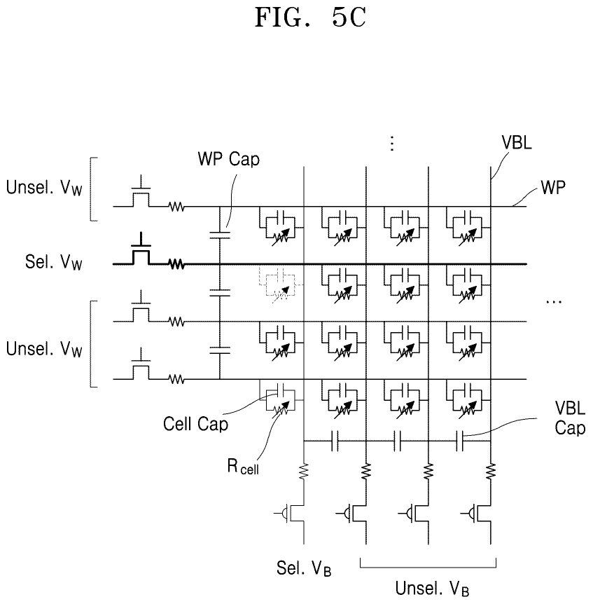

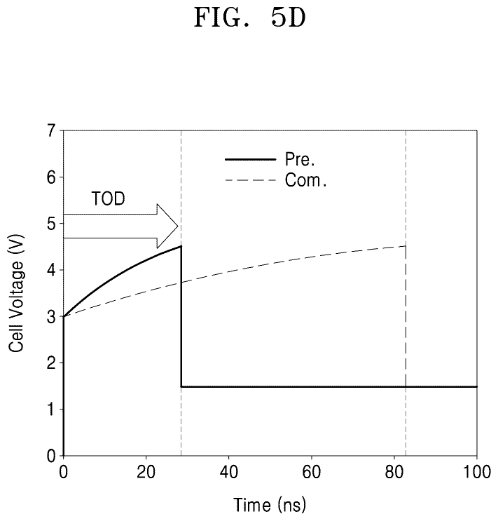

FIGS. 5A to 5D are perspective views, a circuit structure, and a graph of operating characteristics of the Comparative Example and the embodiment of FIG. 1A.

Referring to FIG. 5A, a 3D vertical memory device Com. of the Comparative Example may have a structure in which all electrode structures ES within a cell block of each layer are connected to one gate electrode WP. For example, the gate electrode WP may have a shape of one plate electrode. As described above, in an embodiment in which the gate electrode WP has the shape of one plate electrode, operating speed due to the parasitic cap may decrease and programming current due to the increase in cell leakage may be reduced.

Referring to FIG. 5B, in a case of the 3D vertical memory device 100 of an embodiment of the present disclosure, the electrode structure 110 within a cell block of each layer may have a structure connected to two gate electrodes 122 that are split. For example, in each layer, the gate electrode 122 may include a first plate electrode PE1 and a second plate electrode PE2. As described above, the gate electrode 122 has a shape of a split plate electrode, so that the problems of the 3D vertical memory device Com. of the Comparative Example may be prevented. In FIG. 5B, for convenience, the first carbon layer 114 and the second carbon layer 118 are omitted.

Referring to FIGS. 5C and 5D, the 3D vertical memory device may have a circuit structure as shown in FIG. 5C. In FIG. 5C, VBL indicates a vertical bit line, WP indicates a word line plate, VBL Cap indicates a parasitic cap of a vertical bit line, WP Cap indicates a parasitic cap of a word line plate, Unsel. V_{w} and Unsel. V_{B} indicate voltages of unselected cells, Sel. V_{w} and Sel. V_{B} indicate voltages of selected cells, and Cell Cap and R_{cell} indicate a cell's cap and resistance. For reference, VBL may correspond to the first electrode 112 in the 3D vertical memory device 100 of an embodiment shown in FIG. 1A, WP may correspond to the gate electrode 122, and the Cell Cap and R_{cell} may correspond to the switching material layer 116.

As can be understood through FIG. 5D, the 3D vertical memory device Com. of the Comparative Example having the gate electrode WP that is not split, may have a long turn-on delay (TOD) of about 80 ns, and may have a slow operating speed. On the other hand, the 3D vertical memory device Pre. and 100 having the gate electrode 122 that is split according to an embodiment of the present disclosure may have a short turn-on delay of about 20 to about 30 ns, and may have a fast operating speed.

Hereinabove, the 3D vertical memory device 100 of an embodiment shown in FIG. 1A is described. However, the 3D vertical memory devices 100a and 100b of embodiments shown in FIGS. 2A and 3A may have substantially similar effects.

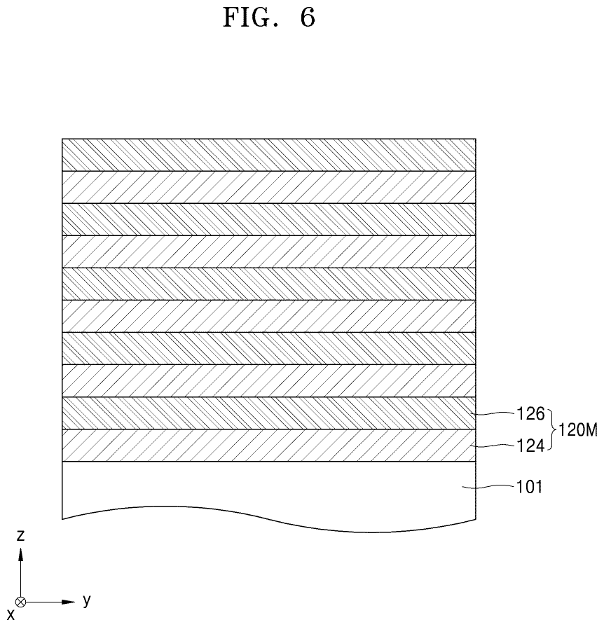

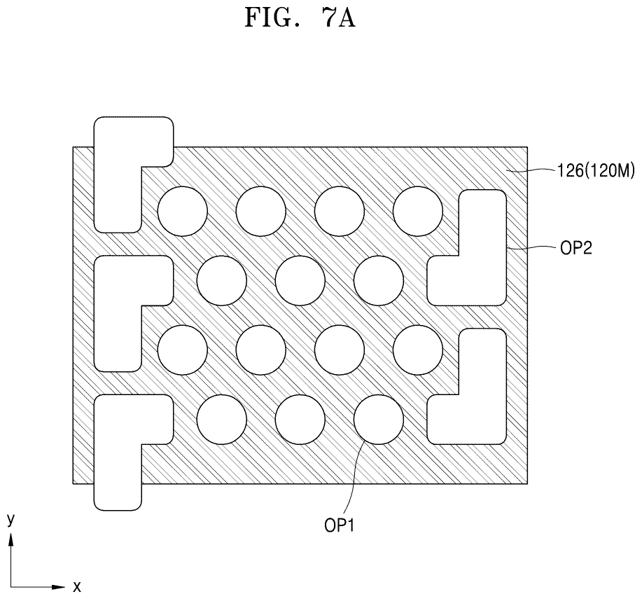

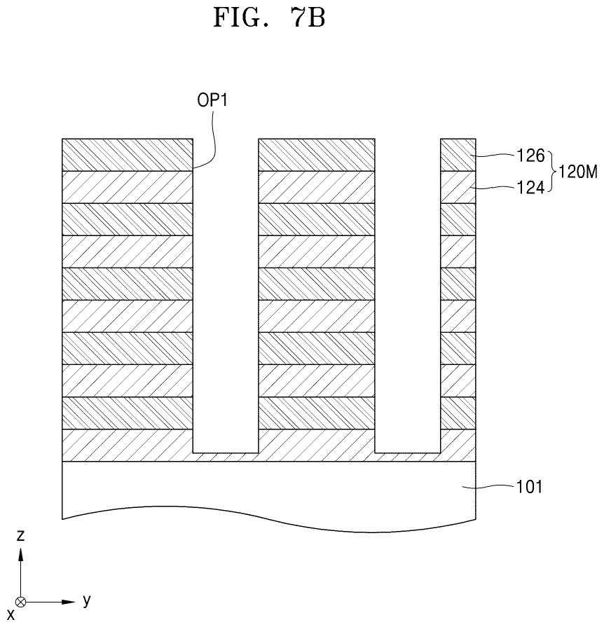

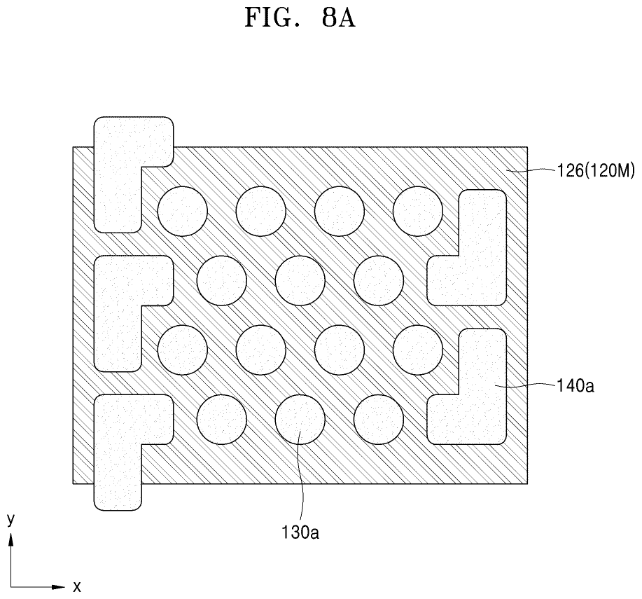

FIGS. 6 to 12B are plan views and cross-sectional views showing a process of manufacturing the 3D vertical memory device 100 of FIGS. 1A and 1B. FIGS. 7A, 8A, 9A, 10A, 11A, and 12A correspond to FIG. 1A, and FIGS. 6, 7B, 8B, 9B, 10B, 11B, and 12B correspond to FIG. 1B. Reference is also made to FIGS. 1A to 1C, and details provided with reference to FIGS. 1A to 5D may be briefly described or omitted for economy of description.

Referring to FIG. 6, in a method of manufacturing a 3D vertical memory device of an embodiment, an interlayer insulating layer 124 and a sacrificial insulating layer 126 may be alternately stacked on a substrate 101 to form a mold structure 120M. The interlayer insulating layer 124 and the sacrificial insulating layer 126 may each include an insulating material, for example, silicon oxide, silicon nitride, or silicon oxynitride. However, the interlayer insulating layer 124 and the sacrificial insulating layer 126 may include a material having etch selectivity with respect to each other. For example, in the method of manufacturing the 3D vertical memory device of an embodiment, the interlayer insulating layer 124 may include silicon oxide, and the sacrificial insulating layer 126 may include silicon nitride. However, as long as the etch selectivity is satisfied, materials of the interlayer insulating layer 124 and the sacrificial insulating layer 126 are not necessarily limited to the materials described above.

Referring to FIGS. 7A and 7B, after the molding structure 120M is formed, a first open hole OP1 and a second open hole OP2 may be formed in an arrangement structure as shown in FIG. 7A. As shown in FIG. 7B, the first open hole OP1 and the second open hole OP2 may open the interlayer insulating layer 124, which is positioned at a lowermost portion, in a form of a recess. For example, the first open hole OP1 and the second open hole OP2 may pass completely through all of the interlayer insulating layers 124 and the sacrificial insulating layers 126 except for the lowermost interlayer insulating layer 124. In addition, recesses due to the first open hole OP1 and the second open hole OP2 may be formed at an upper portion of the lowermost interlayer insulating layer 124.

In an embodiment, the first open hole OP1 may be a through-hole for the partition wall pillar 130. Accordingly, the first open holes OP1 may be arranged to be spaced apart from each other and may constitute a line in the x direction. In addition, in an embodiment the first open holes OP1 may be arranged in a zigzag manner in the x direction, on two lines adjacent to each other in the y direction. For example, the first open holes OP1 may be arranged to have the first pitch P1 in the x direction, and the first open holes OP1 may be arranged to have an offset of ½ of the first pitch P1 in the x direction, between two lines adjacent to each other in the y direction.

In an embodiment, the second open hole OP2 may be a through-hole for the trim pattern 140. Accordingly, the second open hole OP2 may be arranged at an edge portion of a cell block in the x direction, and may have an inverted “L” shape or an “L” shape in a plan view. In addition, the second open hole OP2 may have a width that overlaps two adjacent first open holes OP1 in the y direction. In an embodiment, the second open holes OP2 on the left side in the x direction and the second open holes OP2 on the right side in the x direction may be arranged at staggered positions in the y direction. In addition, two second open holes OP2 facing each other in the x direction may together overlap one line on which the first open holes OP1 are arranged in the x direction, and may be arranged in a point-symmetrical structure with respect to any one portion on the line, for example, the first open hole OP1 of a central portion of the line.

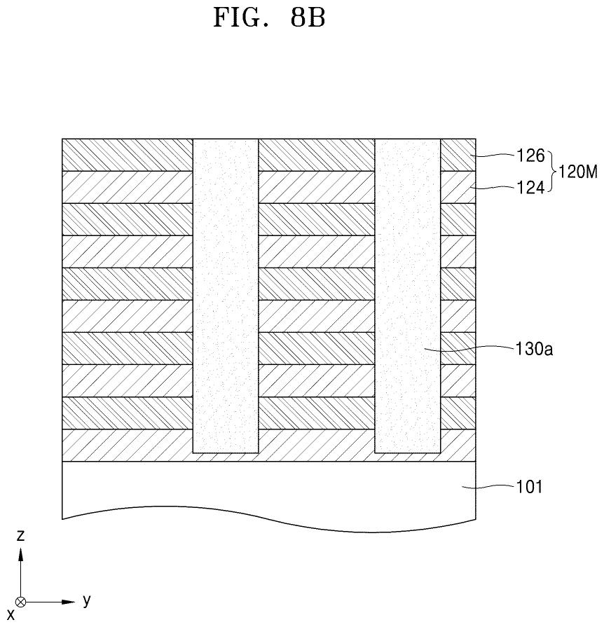

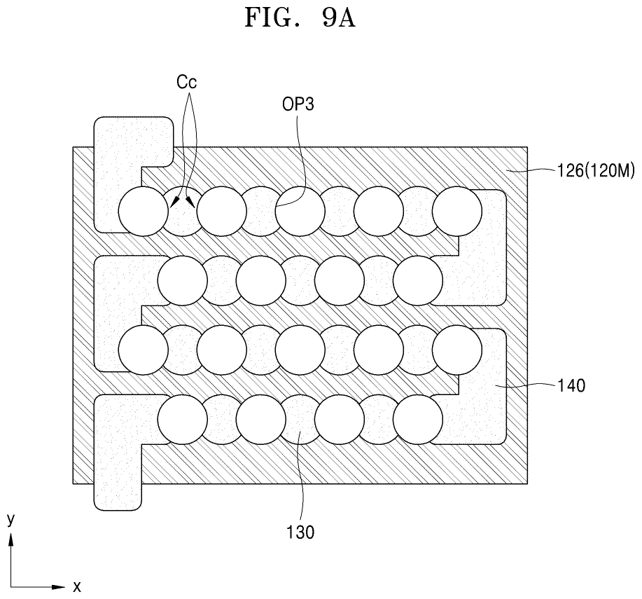

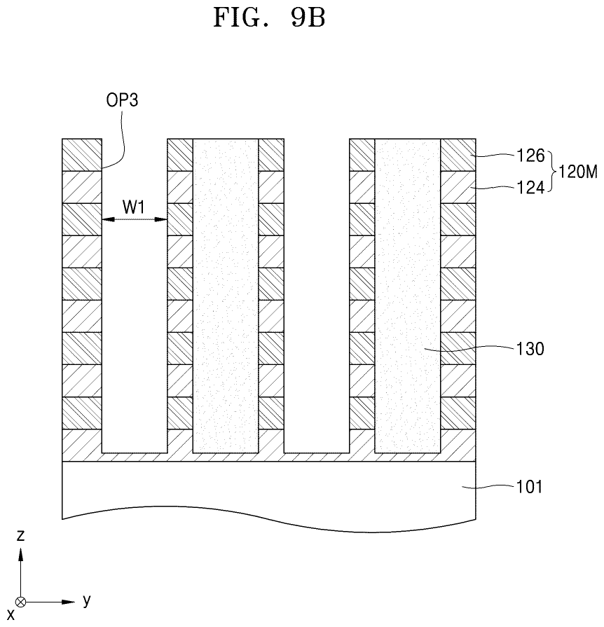

Referring to FIGS. 8A and 8B, in an embodiment after the first open hole OP1 and the second open hole OP2 are formed, the first open hole OP1 and the second open hole OP2 may be filled with a first insulating material and planarized. For example, the first insulating material may include substantially a same material as the interlayer insulating layer 124. For example, in an embodiment the first open hole OP1 and the second open hole OP2 may be filled with silicon oxide. However, the first insulating material that fills the first open hole OP1 and the second open hole OP2 is not necessarily limited to silicon oxide. After planarization, the first insulating material filling the first open hole OP1 may be an initial partition wall pillar 130a, and the first insulating material filling the second open hole OP2 may be an initial trim pattern 140a.

Referring to FIGS. 9A and 9B, in an embodiment after the initial partition wall pillar 130a and the initial trim pattern 140a are formed, a third open hole OP3 may be formed in an arrangement structure as shown in FIG. 9A. The third open hole OP3 may open the interlayer insulating layer 124 located at a lowermost portion, in a form of a recess. For example, the third open hole OP3 may pass completely through interlayer insulating layers 124 and the sacrificial insulating layers 126 except for the interlayer insulating layer 124 positioned at the lowermost portion. In addition, a recess due to the third open hole OP3 may be formed in the upper portion of the interlayer insulating layer located at the lowermost portion.

In an embodiment, the third open hole OP3 may be a through-hole for the electrode structure 110. Accordingly, the third open holes OP3 may be arranged to be spaced apart from each other and may constitute a line in the x direction. Through this formation of the third open hole OP3, the partition wall pillar 130 having concave portions Ce at opposite sides thereof in the x direction may be formed. The third open holes OP3 may be arranged in a zigzag manner in the x direction on two lines adjacent to each other in the y direction. For example, the third open holes OP3 may be arranged to have the first pitch P1 in the x direction, and the third open holes OP3 may be arranged to have ½ of the first pitch P1 in the x direction, between the two lines adjacent to each other in the y direction

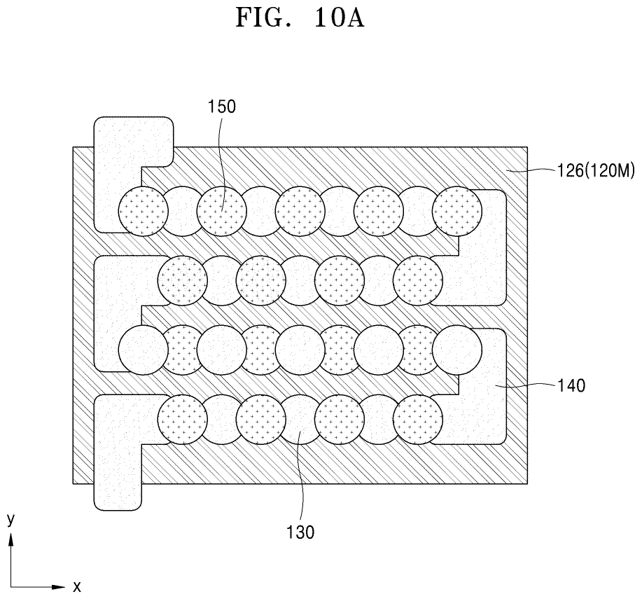

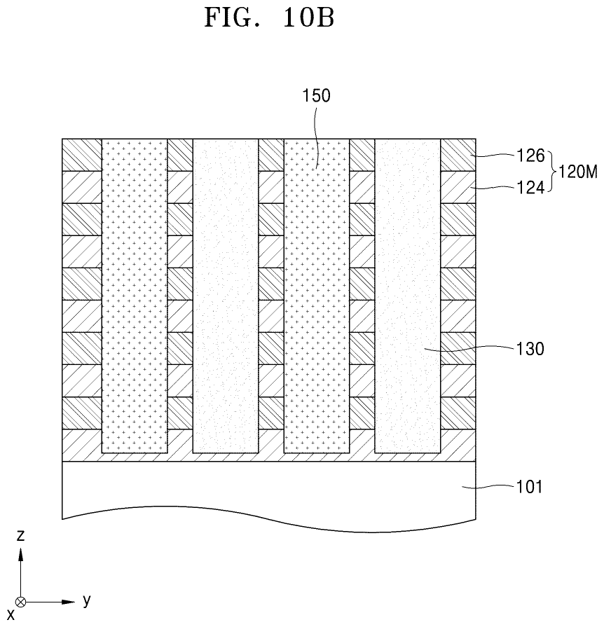

Referring to FIGS. 10A and 10B, in an embodiment after the third open hole OP3 is formed, the third open hole OP3 may be filled with a sacrificial material and planarized. In an embodiment, the sacrificial material may include a material having etch selectivity with respect to each of the interlayer insulating layer 124 and the sacrificial insulating layer 126. For example, in an embodiment in which the interlayer insulating layer 124 includes silicon oxide, and the sacrificial insulating layer 126 includes silicon nitride, the sacrificial material filling the third open hole OP3 may include polysilicon. However, the sacrificial material filling the third open hole OP3 is not necessarily limited to polysilicon. After planarization, the sacrificial material filling the third open hole OP3 may be a pillar 150 for an electrode structure.

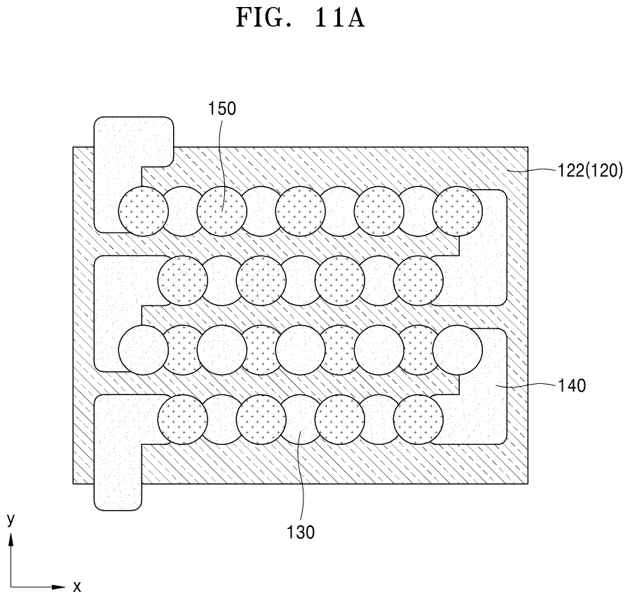

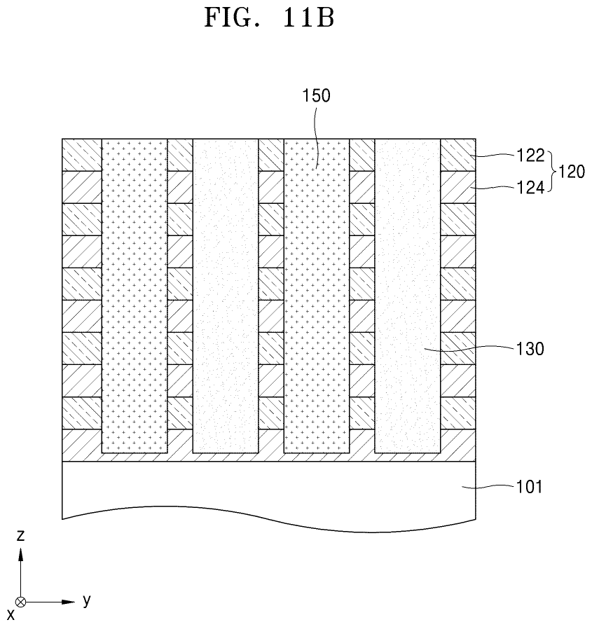

Referring to FIGS. 11A and 11B, after the pillar 150 for an electrode structure is formed, the sacrificial insulating layer 126 is changed to the gate electrode 122 through a replacement process. To briefly describe the replacement process, in an embodiment trenches for a separation area having a certain interval in the x direction and extending in the y direction may be formed. The interlayer insulating layer 124 and the sacrificial insulating layer 126 may be exposed through sidewalls of the trenches for a separation area. Thereafter, the exposed sacrificial insulating layer 126 may be removed through wet etching, and the removed portion may be filled with a conductive material to form the gate electrode 122. In an embodiment, the conductive material may include, for example, a doped semiconductor material, a metal, a conductive metal nitride, or a conductive metal oxide.

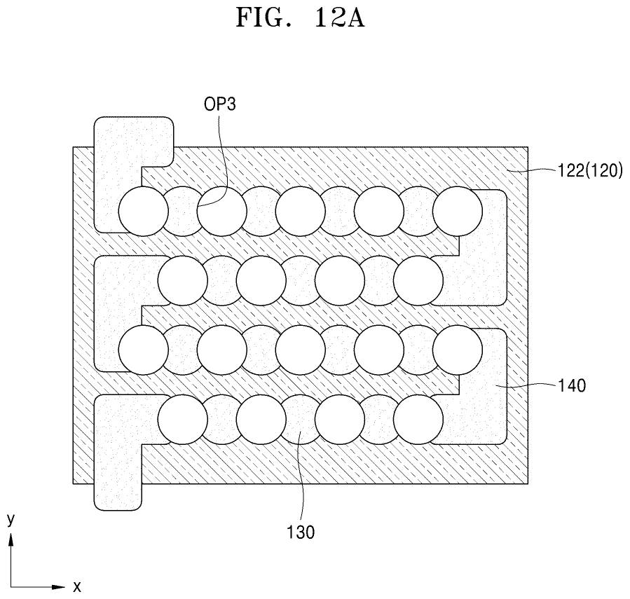

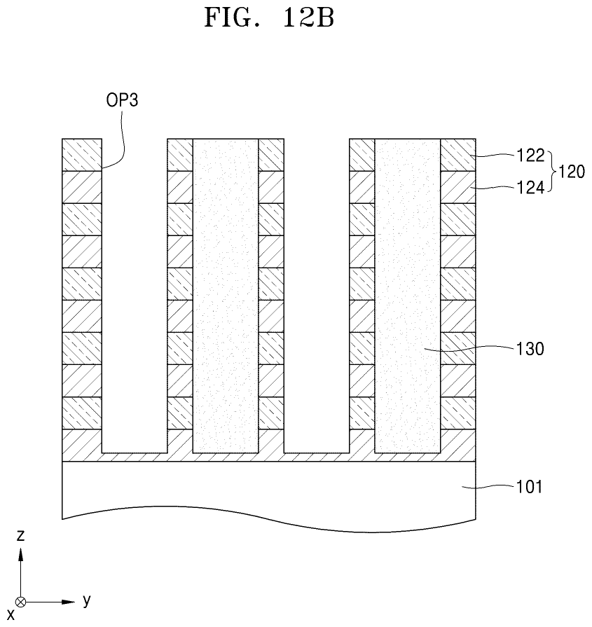

Referring to FIGS. 12A and 12B, in an embodiment after the formation of the gate electrode 122, the pillar 150 for an electrode structure may be removed through etching to form the third open hole OP3 again. Thereafter, the second carbon layer 118, the switching material layer 116, the first carbon layer 114, and the first electrode 112 may be sequentially formed within the third open hole OP3 to complete the 3D vertical memory device 100 of FIG. 1A.

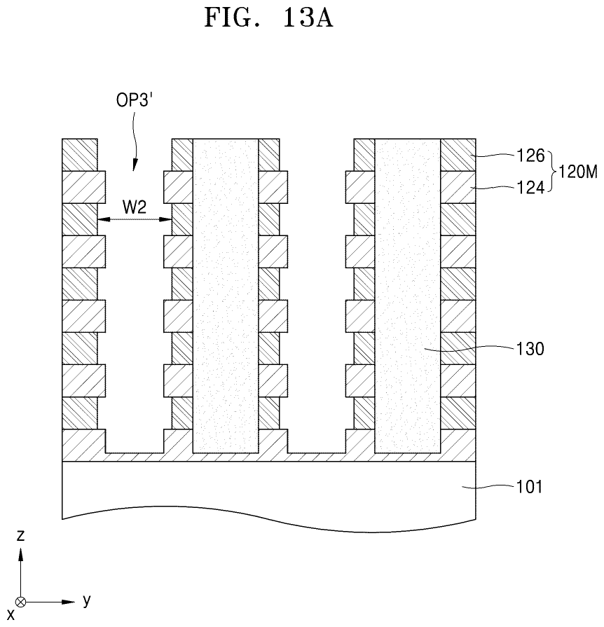

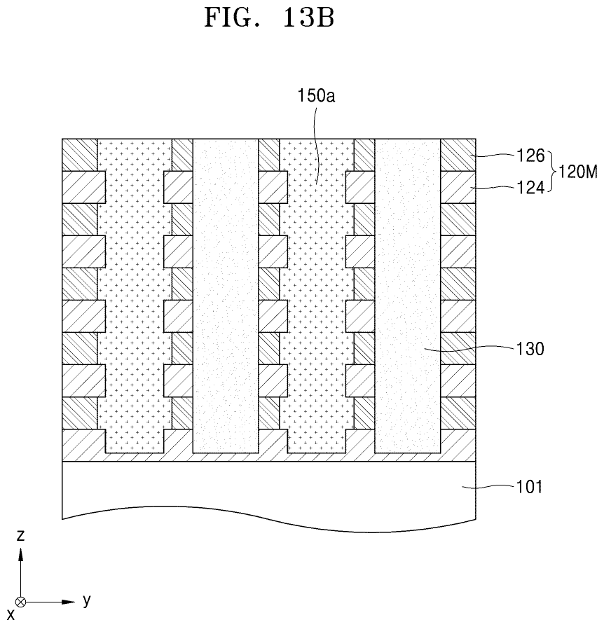

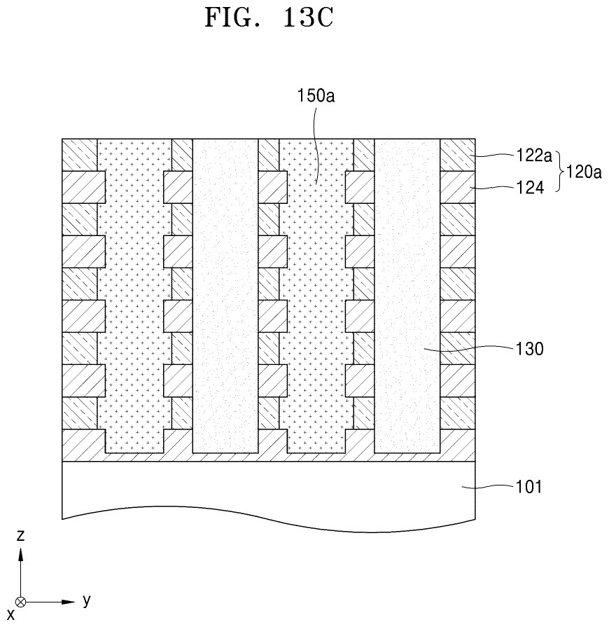

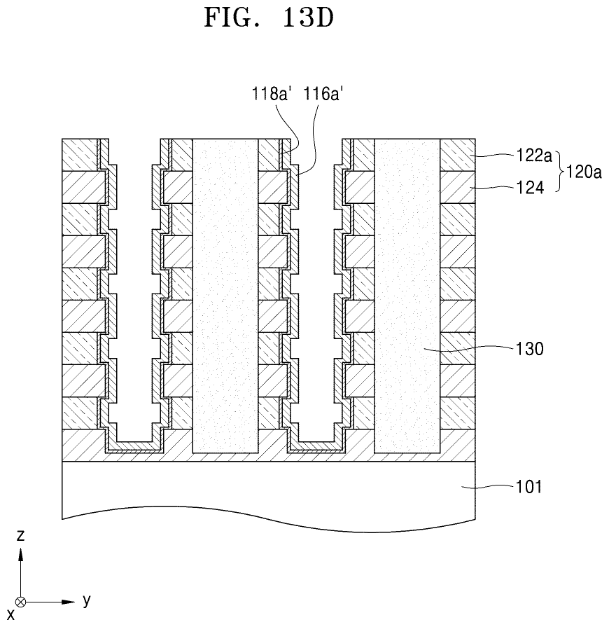

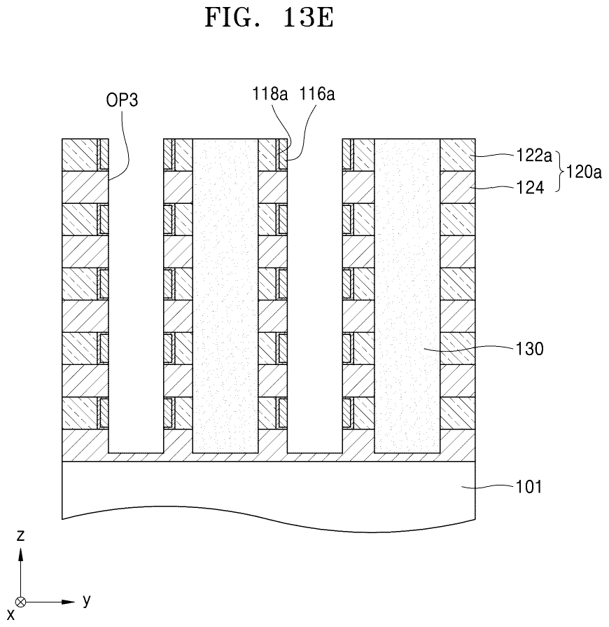

FIGS. 13A to 13E are cross-sectional views showing a process of manufacturing the 3D vertical memory device 100a of an embodiment shown in FIG. 2B. FIGS. 13A to 13E correspond to FIG. 2B. Reference is also made to FIGS. 2A to 2C, and details provided with reference to FIGS. 6 to 12B may be briefly described or omitted for economy of description.

Referring to FIG. 13A, in the method of manufacturing the 3D vertical memory device, of an embodiment, the third open hole OP3 may be formed on the substrate 101 through the processes shown in FIGS. 5 to 9B. The third open hole OP3 may correspond to an initial through-hole for the electrode structure 110a. After the formation of the third open hole OP3, a portion of the sacrificial insulating layer 126 exposed through the third open hole OP3 may be etched through an etching process. Through etching of the portion of the sacrificial insulating layer 126, a third open hole OP3′ in which recesses are formed at opposite side portions in the y direction may be formed.

In FIG. 9B, which is before the formation of the recesses, a width of the third open hole OP3 in the y direction may be the first width W1. In addition, after the recesses are formed, a width in the y direction at a recess portion of the third open hole OP3′ may be the second width W2, and the second width W2 may be greater than the first width W1. The second width W2 may be appropriately adjusted considering the entire size, such as the diameter, of the electrode structure 110a to be formed later. In a embodiment, since the partition wall pillars 130 are present at opposite sides of the third open hole OP3′ in the x direction, the increase in width in the x direction may be little or, if at all, very small.

Referring to FIG. 13B, in an embodiment after the third open hole OP3′ is formed, similar to FIG. 10B, the third open hole OP3′ may be filled with the sacrificial material and planarized. In an embodiment, the sacrificial material may include a material having etch selectivity with respect to each of the interlayer insulating layer 124 and the sacrificial insulating layer 126. For example, in an embodiment in which the interlayer insulating layer 124 includes silicon oxide, and the sacrificial insulating layer 126 includes silicon nitride, the sacrificial material filling the third open hole OP3′ may include polysilicon. However, the sacrificial material filling the third open hole OP3′ is not necessarily limited to polysilicon. After planarization, the sacrificial material filling the third open hole OP3′ may be a pillar 150a for an electrode structure.

Referring to FIG. 13C, in an embodiment, after the formation of the pillar 150a for an electrode structure, the sacrificial insulating layer 126 may be changed to the gate electrode 122a through a replacement process. The replacement process is same as described with reference to embodiments of FIGS. 11A and 11B.

Referring to FIG. 13D, after the formation of the gate electrode 122a, the pillar 150a for an electrode structure may be removed through etching so as to form the third open hole OP3′ again. Thereafter, a second carbon layer 118a′ and a switching material layer 116a′ may be sequentially formed with a uniform thickness within the third open hole OP3′. Due to recesses within the third open holes OP3′, the second carbon layer 118a′ and the switching material layer 116a′ may have concave-convex shapes, as shown in FIG. 13D.

Referring to FIG. 13E, in an embodiment, after the second carbon layer 118a′ and the switching material layer 116a′ are formed within the third open hole OP3′, portions of the second carbon layer 118a′ and the switching material layer 116a′ protruding by the interlayer insulating layer 124 in the third open hole OP3′ may be removed through etching. In an embodiment, the etching may include, for example, etch-back, dry etching, etc. Through this etching process, the second carbon layer 118a and the switching material layer 116a may be formed only within a recess of each layer.

For reference, when protrusions of the second carbon layer 118a′ and the switching material layer 116a′ are referred to as spacers, an etching process for removing the protrusions may be referred to as a spacer etching process. In addition, since the second carbon layer 118a′ and the switching material layer 116a′ between layers are separated from each other through an etching process, the etching process for removing the protrusions may be referred to as a separation etching process. Hereafter, for unity, the etching process for removing the protrusions is described as a spacer etching process.

After the spacer etching process, the third open hole OP3 may be formed again. Thereafter, the first carbon layer 114 and the first electrode 112 may be sequentially formed within the third open hole OP3 to complete the 3D vertical memory device 100a of an embodiment shown in FIG. 2A.

Further, to briefly describe a process of manufacturing the 3D vertical memory device 100b of an embodiment shown in FIG. 3B, first, in the process of FIG. 13A, a recess may be formed with a very thin depth A gate electrode may be formed through the processes of embodiments shown in FIGS. 13B and 13C. In the process of FIG. 13D, a second carbon layer may be formed. In the process of FIG. 13E, the second carbon layer may be maintained only in the recess through a spacer etching process. Thereafter, a switching material layer, a first carbon layer, and a first electrode may be sequentially formed on the second carbon layer to complete the 3D vertical memory device 100b of FIG. 3A.

While the present disclosure has been particularly shown and described with reference to non-limiting embodiments thereof, it will be understood that various changes in form and details may be made therein without departing from the spirit and scope of the present disclosure.

What is claimed is:

1. A three-dimensional (3D) vertical memory device, comprising:
a substrate;
an electrode structure extending in a vertical direction on the substrate, the electrode structure having a shape of a first cylinder, the electrode structure comprising a first electrode and a switching material layer, and
a gate stack structure comprising a gate electrode and an interlayer insulating layer that are alternately stacked on the substrate along a sidewall of the electrode structure, the gate electrode is electrically connected to the switching material layer,
wherein the electrode structure is arranged in a two-dimensional array structure on a plane perpendicular to the vertical direction, and constitutes a plurality of lines extending in a first direction on the plane,
on the plane, the electrode structures of two lines adjacent to each other in a second direction perpendicular to the first direction are arranged in a zigzag manner in the first direction with an offset of a ½ pitch in the first direction, and
a partition wall pillar having a shape of a second cylinder is arranged between the electrode structures adjacent to each other in the first direction.

2. The 3D vertical memory device of claim 1, wherein:
the first cylinder and the second cylinder partially overlap each other in the first direction;
a horizontal cross section of the first cylinder has a circular shape; and
a horizontal cross section of the second cylinder comprises a concave portion at opposite sides thereof in the first direction.

3. The 3D vertical memory device of claim 1, wherein, on the plane, a trim pattern having an inverted “L” shape or an “L” shape is arranged at edges of the plurality of lines of the electrode structure at opposite sides in the first direction, the trim pattern is composed of a same material as the partition wall pillar.

4. The 3D vertical memory device of claim 3, wherein:
the trim pattern has a width overlapping two of the partition wall pillar in the second direction; and
the trim pattern on a left side in the first direction and the trim pattern on a right side in the first direction are arranged at staggered positions in the second direction with respect to each other.

5. The 3D vertical memory device of claim 1, wherein:
the first electrode is arranged in a central portion of the first cylinder, the first electrode having a shape of a third cylinder having a smaller diameter than the first cylinder; and
the switching material layer has a circular pipe shape extending in the vertical direction and surrounding the first electrode.

6. The 3D vertical memory device of claim 5, wherein the switching material layer comprises a bottom surface that covers a lower surface of the third cylinder.

7. The 3D vertical memory device of claim 5, further comprising:
a first carbon layer arranged between the first electrode and the switching material layer; and
a second carbon layer arranged between the gate electrode and the switching material layer.

8. The 3D vertical memory device of claim 7, wherein the first carbon layer and the second carbon layer have a circular pipe shape.

9. The 3D vertical memory device of claim 1, wherein:
the first electrode is arranged in a central portion of the first cylinder and has a shape of a third cylinder having a smaller diameter than the first cylinder;
the switching material layer comprises a plurality of switching elements that are spaced apart from each other by the interlayer insulating layer in the vertical direction; and
each of the switching elements has a shape of two arcs surrounding a portion of the first electrode and facing each other.

10. The 3D vertical memory device of claim 9, further comprising:
a first carbon layer arranged between the first electrode and the switching material layer; and
a second carbon layer arranged between the gate electrode and the switching material layer.

11. The 3D vertical memory device of claim 10, wherein:
the first carbon layer has a circular pipe shape surrounding a lower surface and lateral side surfaces of the first electrode; and
the second carbon layer comprises second carbon elements corresponding to the switching elements, the second carbon elements each having a shape of two arcs.

12. A three-dimensional (3D) vertical memory device, comprising:
a substrate;
a first electrode on the substrate, the first electrode extending in a vertical direction and having a shape of a first cylinder;
a switching material layer having a circular pipe shape extending in the vertical direction and surrounding the first electrode; and
a gate stack structure comprising a gate electrode and an interlayer insulating layer that are alternately stacked on the substrate along a sidewall of the switching material layer, the gate electrode is electrically connected to the switching material layer,
wherein the first electrode and the switching material layer together have a shape of a second cylinder, wherein the second cylinder is arranged in a two-dimensional array structure on a plane perpendicular to the vertical direction, and constitutes a plurality of lines extending in a first direction on the plane,
on the plane, the second cylinders of two lines adjacent to each other in a second direction perpendicular to the first direction are arranged in a zigzag manner in the first direction with an offset of a ½ pitch in the first direction, and
a partition wall pillar having a shape of a third cylinder is arranged between the second cylinders adjacent to each other in the first direction.

13. The 3D vertical memory device of claim 12, wherein:
the second cylinder and the third cylinder partially overlap each other in the first direction,
a horizontal cross section of the second cylinder has a circular shape; and
a horizontal cross section of the third cylinder comprises a concave portion at opposite sides thereof in the first direction.

14. The 3D vertical memory device of claim 12, wherein, on the plane, a trim pattern having an inverted “L” shape or an “L” shape is arranged at edges of the plurality of lines at opposite sides in the first direction, the trim pattern is composed of a same material as the partition wall pillar.

15. The 3D vertical memory device of claim 12, further comprising:
a first carbon layer arranged between the first electrode and the switching material layer; and
a second carbon layer arranged between the gate electrode and the switching material layer.

16. The 3D vertical memory device of claim 15, wherein the first carbon layer and the second carbon layer have a circular pipe shape.

17. A three-dimensional (3D) vertical memory device, comprising:
a substrate;
a first electrode on the substrate, the first electrode extending in a vertical direction and having a shape of a first cylinder;
a switching material layer comprising a plurality of switching elements that are spaced apart from each other by layer in the vertical direction, wherein the plurality of switching elements each have a shape of two arcs surrounding a portion of the first electrode and facing each other; and
a gate stack structure comprising a gate electrode and an interlayer insulating layer that are alternately stacked on the substrate along a side wall of the first electrode, the gate electrode is electrically connected to the switching material layer,
wherein the first cylinder is arranged in a two-dimensional array structure on a plane perpendicular to the vertical direction, and constitutes a plurality of lines extending in a first direction on the plane,
on the plane, the first cylinders of two lines adjacent to each other in a second direction perpendicular to the first direction are arranged in a zigzag manner in the first direction with an offset of a ½ pitch in the first direction, and
a partition wall pillar having a shape of a second cylinder is arranged between the first cylinders adjacent to each other in the first direction.

18. The 3D vertical memory device of claim 17, wherein, on the plane, a trim pattern having an inverted “L” shape or an “L” shape is arranged at edges of the plurality of lines at opposite sides in the first direction, the trim pattern is composed of a same material as the partition wall pillar.

19. The 3D vertical memory device of claim 17, further comprising:
a first carbon layer arranged between the first electrode and the switching material layer; and
a second carbon layer arranged between the gate electrode and the switching material layer.

20. The 3D vertical memory device of claim 19, wherein:
the first carbon layer has a circular pipe shape surrounding a lower surface and lateral side surfaces of the first electrode; and
the second carbon layer comprises second carbon elements corresponding to the switching elements, the second carbon elements each having a shape of two arcs.
